(19) United States
(12) Patent Application Publication
(10) Pub. No.: US 2020/0174205 A1
(43) Pub. Date: Jun. 4, 2020

(54) OPTICAL COMPONENT AND OPTICAL MODULE USING THE SAME

(71) Applicants: FUJITSU LIMITED, Kawasaki-shi (JP); Fujitsu Optical Components Limited, Kawasaki-shi (JP)

(72) Inventors: Teruhiro KUBO, Kitahiroshima (JP); Kohei SHIBATA, lsehara (JP); Hiroshi KOBAYASHI, Kawasaki (JP); Naoki ISHIKAWA, Nagano (JP)

(73) Assignees: FUJITSU LIMITED, Kawasaki-shi (JP); Fujitsu Optical Components Limited, Kawasaki-shi (JP)

(21) Appl. No.: 16/695,720

(22) Filed: Nov. 26, 2019

(30) Foreign Application Priority Data
Nov. 30, 2018 (JP) 2018-225301

(51) Int. Cl. G02B 6/42; H01L 23/13; H01L 23/498; H01L 23/367; H01L 23/00; H05K 1/18; H05K 1/11; H05K 5/06; H05K 5/02; H05K 5/00

(52) U.S. Cl. CPC G02B 6/4238; H01L 2924/3512; G02B 6/4269; H01L 23/13; H01L 23/49838; H01L 23/3675; H01L 24/48; H05K 1/181; H05K 1/111; G02B 6/4251; H05K 5/069; H01L 23/49816; H01L 23/49822; H05K 5/0247; H05K 5/0004; H05K 2201/10121; H05K 2201/10734; H01L 2224/48091; H01L 2224/48101; H01L 2224/48157; G02B 6/4274

(57) ABSTRACT

An optical component configured to be mounted on a circuit board has a casing made of a ceramic electrical insulator and having a cavity, a photonic circuit device provided in the cavity, a lid configured to cover the cavity, and protruding electrodes provided along an outer periphery of the cavity of the casing, wherein a first linear expansion coefficient of the casing is smaller than a second linear expansion coefficient of the circuit board, and a third linear expansion coefficient of the lid is greater than the second linear expansion coefficient of the circuit board.

### CROSS-REFERENCE TO RELATED APPLICATIONS

This application is based upon and claims priority to earlier filed Japanese Patent Application No. 2018-225301 filed Nov. 30, 2018, which is incorporated herein by reference in its entirety.

### FIELD

The present invention relates to an optical component, and an optical module using the same.

### BACKGROUND

In recent years, there has been demand for an optical module in which optoelectronic devices and components are integrated to have a pluggable shape, as well as a compact form and high-speed transmission ability. Pluggable optical transceiver modules are becoming mainstream not only for short-range data center networks, but also for optical metro network interfaces. In order for downsizing and high-data-rate transmission, a design for integrating optical devices together with a control circuit for them in the same package is being adopted.

For electronic devices such as LSI chips, flip-chip mounting is typically adopted using a fine-pitch solder ball grid array (BGA). A configuration in which a semiconductor IC chip is accommodated in a cavity with a cover provided thereto is known (see, for example, Patent Documents 1 and 2 presented below).

### PRIOR ART DOCUMENTS

Patent Document 1: U.S. Pat. No. 5,032,897
Patent Document 2: PCT Publication WO 97/04629

When an optical component is packaged, the size of the bonding electrodes (such as solder balls) is determined by the impedance set so as to match the high-frequency characteristics of optical communication. Accordingly, the margin with respect to stress is severe, and cracks or the like occur easily in the bonded portion due to external stress. The same problem occurs when an optical component and a substrate are bonded to each other by pillar-shaped protruding electrodes.

When an electronic device is flip-chip mounted using a BGA of solder balls, resin sealing is implemented typically using an underfill resin in order for compensating for the insufficient bonding strength of the solder balls. However, as for an optical component, there may be some portions where application of an underfill resin is undesirable, especially in a bonding or connecting part through which high-speed signal transfer is carried out, from the viewpoint of eliminating influence of variation in the dielectric constant.

It is desired to reduce a stress applied to the connecting or bonding part that connects an optical component onto a substrate and to improve connection reliability.

### SUMMARY

In one aspect of the invention, an optical component configured to be mounted on a circuit board includes
a casing made of a ceramic electrical insulator and having a cavity,
a photonic circuit device provided in the cavity,
a lid configured to cover the cavity, and
protruding electrodes provided along an outer periphery of the cavity of the casing,
wherein a first linear expansion coefficient of the casing is smaller than a second linear expansion coefficient of the circuit board, and a third linear expansion coefficient of the lid is greater than the second linear expansion coefficient of the circuit board.

The object and advantages of the invention will be realized and attained by means of the elements and combinations particularly pointed out in the claims. It is to be understood that both the foregoing general description and the following detailed description are exemplary and explanatory and are not restrictive to the invention as claimed.

### BRIEF DESCRIPTION OF DRAWINGS

FIG. 1 illustrates a configuration example of an optical module to which an optical component of an embodiment is applied;

FIG. 2 is a schematic cross-sectional view of the optical component used in FIG. 1;

FIG. 3 is a cross-sectional view taken along the X-X′ line of FIG. 1;

FIG. 4 illustrates stress distribution due to a difference in the lid material;

FIG. 5 illustrates a model used for calculation of FIG. 4;

FIG. 6 is a diagram illustrating a ball-diameter dependency of the maximum stress applied to the solder ball;

FIG. 7 illustrates an example of the solder ball;

FIG. 8 illustrates a modification of the optical component;

FIG. 9 is a schematic diagram of a circuit board on which the optical component of FIG. 8 is mounted;

FIG. 10 illustrates an assembled structure of the optical component of FIG. 8;

FIG. 11 illustrates another modification of the optical component;

FIG. 12 is a schematic diagram of a circuit board on which the optical component of FIG. 11 is mounted;

FIG. 13 illustrates an assembled structure of the optical component of FIG. 11; and

FIG. 14 illustrates another example of the optical module using an optical component.

### DESCRIPTION OF EMBODIMENTS

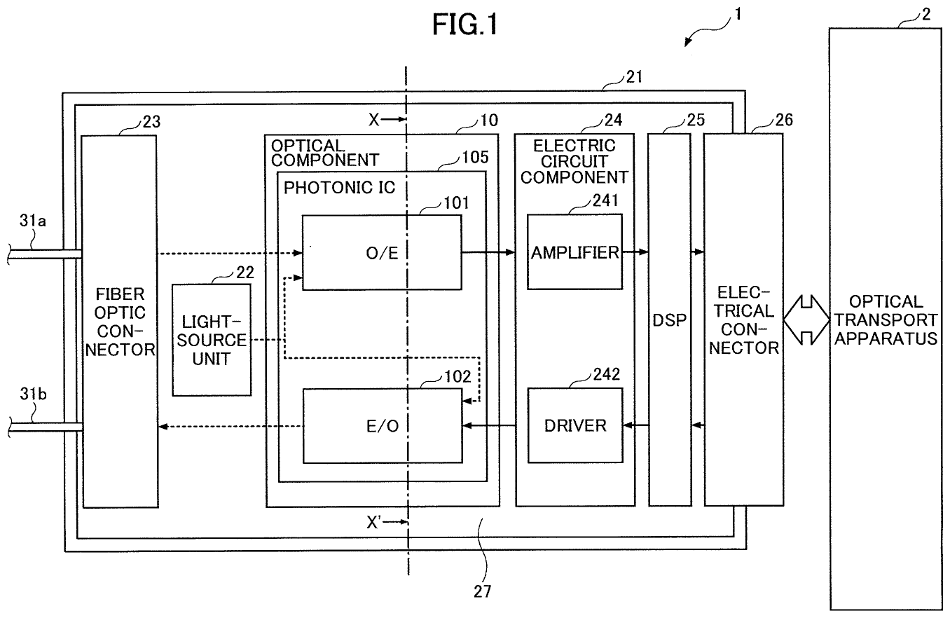

FIG. 1 is a schematic diagram of an optical module 1 using an optical component 10 according to an embodiment. The optical module 1 is, for example, a pluggable optical transceiver, and it is configured so as to be plugged into and unplugged from the optical transport apparatus 2.

The optical module 1 has a circuit board 27 in a package 21. The circuit board 27 serves as a module board, and an optical component 10, a light source unit 22, an electric circuit component 24, and a digital signal processor (DSP) 25 are mounted on the circuit board 27. Although in this example the light source unit 22 and the DSP 25 are built in the optical module 1, at least one of the light source unit 22 and the DSP 25 may be provided outside the package 21.

The optical module 1 has a pluggable electrical connector 26 at a side for connection to the optical transport apparatus 2, and an optical connector 23 connected to optical fibers 31a and 31b at a side of the optical transmission path. The optical connector 23 may also be a pluggable connector for receiving optical fibers 31a and 31b.

The optical component 10 has a photonic integrated circuit (IC) 105 accommodated in a casing and it is flip-chip mounted on the circuit board 27. The optical component 10 serves as a front-end circuit for optical transmission and reception and includes an optical to electric (O/E) converter circuit 101 and an electrical to optical (E/O) converter circuit 102.

The O/E converter circuit 101 includes, for example, an optical waveguide circuit fabricated by silicon photonics technology, as well as light sensitive devices. The circuit elements formed by the optical waveguide include, but are not limited to, a polarizing beam splitter, a 90-degree hybrid optical mixer, or the like. When a germanium (Ge) photodiode is used as the light sensitive device, such light sensitive devices may be integrated onto the silicon substrate together with other circuit elements. When a compound semiconductor light sensitive device is used, it may be provided separately from the other circuit elements on the silicon substrate.

The E/O converter circuit 102 includes, for example, a semiconductor based electro-absorption modulator.

In a configuration in which the optical module 1 is plugged in or connected to the optical transport apparatus 2 via the electrical connector 26, an optical signal received from the optical fiber 31a is input to the O/E converter circuit 101 of the optical component 10 through the optical connector 23. The O/E converter circuit 101 carries out, for example, splitting the input light into two polarized waves and detecting in-phase (I) component and quadrature (Q) component for each of the polarized waves at the 90-degree hybrid optical mixer. The light components with 90-degree phase shifted from each other are detected for each of the polarized waves at the associated light sensitive devices, and photocurrents proportional to the quantities of the light components are output.

The photocurrents output from the optical component 10 are supplied to the electric circuit component 24 through the circuit board 27. The photocurrents are converted into electric voltage signals and amplified by the amplifier 241 of the electric circuit component 24, and supplied to the DSP 25. The DSP 25 performs analog to digital (A/D) conversion and compensation for waveform distortion, and sends the digital signals through the electrical connector 26 to the optical transport apparatus 2.

At the transmission side, a data signal supplied from the optical transport apparatus 2 is subjected to error correction coding, mapping to electric field information (representing phase and amplitude) according to the logical value of the data, waveform processing, etc. by the DSP 25, and input to the driver 242 of the electric circuit component 24. The driver 242 generates a high-speed analog drive signal from the inputted digital signal. The generated analog drive signal is input to the E/O converter circuit 102 of the optical component 10 through the circuit board 27.

The optical modulator in the E/O converter circuit 102 is configured to modulate the light incident from the light source unit 22 with the analog drive signal and outputs a modulated optical signal to the optical fiber 31b.

The optical component 10 used in the optical module 1 is mounted, together with other components, on the circuit board 27, and configured to output and receive high-frequency electrical signals to and from the electric circuit component 24 via the circuit board 27. For this reason, highly reliable connection strength is required for the bonding part between the optical component 10 and the circuit board 27.

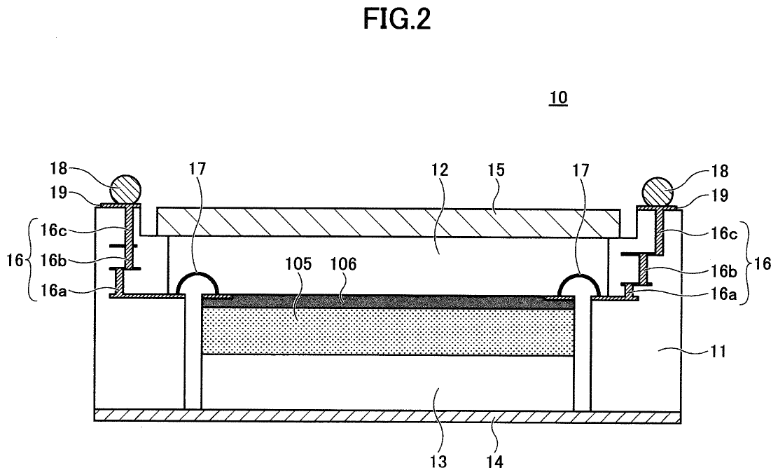

FIG. 2 is a schematic cross-sectional view of the optical component 10 used in FIG. 1. The optical component 10 has a ceramic electrical insulating casing 11, a photonic IC 105 provided in a cavity 12 of the casing 11, and a lid 15 that covers the cavity 12. A large number of protruding electrodes are formed along the outer periphery of the cavity 12 of the casing 11 so as to allow the optical component 10 to be mounted on the circuit board 27. In this example, the protruding electrodes are solder balls 18.

The solder material is preferably a low-temperature to medium-temperature solder material for use in connection of the optical component 10, and examples of such material include, but are not limited to, SnAgCu (SAC), Sn—In—Ag—Bi, Sn—Ag—Bi—Cu, Sn—An—Bi, Sn—Bi, and Sn—In.

The casing 11 is provided with electrical interconnects 16, and at least a part of the solder balls 18 are connected to the electrical interconnects 16. In the example of FIG. 2, electric interconnects 16a to 16c of three layers are formed in the casing 11, and the solder balls 18 are mounted on the electrode pads 19 connected to the electric interconnect 16c. It should be understood that the present invention is not limited to this example, and a multilayer interconnect with a required number of layers may be formed.

It is desirable for the casing 11 to have a strength enough to withstand fabrication of a multilayer interconnect and sealing with the lid 15. As one example, the casing 11 is formed of a ceramic electric insulator. Examples of the ceramic insulator include, but are not limited to, alumina (Al₂O₃), aluminum nitride (AlN), mullite (3Al₂O₃2SiO₂), steatite (MgO SiO₂), and forsterite (2MgO SiO₂).

The linear thermal expansion coefficient (hereinafter, which may be referred to simply as “linear expansion coefficient”) of alumina, aluminum nitride, and steatite is around 7 ppm/° C., the linear expansion coefficient of mullite is about 4 ppm/° C., and the linear expansion coefficient of forsterite is about 10.5 ppm/° C. The difference in the linear expansion coefficient between the circuit board 27 and these casing materials is large. When a resin substrate such as FR-4 is used as the circuit board 27, the linear expansion coefficient is 13 ppm/° C. When copper (Cu) interconnects are formed in the resin substrate, the linear expansion coefficient of such interconnects is 17 ppm/° C. The linear expansion coefficients of the major materials used in the optical component 10 are listed below.
Silicon (for photonic IC): 6 ppm/° C.
Alumina (for casing): 7 ppm/° C.
SAC Solder (for protruding electrode): 20 ppm/° C.
FR-4 (for circuit board): 13 ppm/° C.
Cu (for interconnects) 17 ppm/° C.

In the embodiment, in order for absorbing the difference in the linear expansion coefficient between the casing 11 and the circuit board 27, the lid 15 is formed of a material having a large linear expansion coefficient. The linear expansion coefficient of the lid 15 is greater than that of the circuit board 27, while the linear expansion coefficient of the casing 11 is smaller than that of the circuit board 27. Assuming that the linear expansion coefficients of the casing 11, the circuit board 27 and Lid 15 are CTE_{CASE}, CTE_{PCB}, and CTE_{LID}, respectively, then the optical component 10 is fabricated using materials that satisfies, for example, the relationship

CTE_{CASE}<CTE_{PCB}<CTE_{LID}.

In a preferred example, the optical component 10 is designed such that the overall linear expansion coefficient of a combination of the lid 15 and the casing 11 becomes substantially equal to the linear expansion coefficient of the circuit board 27. Examples of the material of the lid 15 that satisfies the above-described condition include, but are not limited to, Cu, Al, and SUS (stainless steel).

The photonic IC 105 has an optical circuit 106 formed by an optical waveguide. In the optical circuit 106, those parts that carry out optical to electric conversion and electric to optical conversion are connected to the interconnects 16 formed in the casing 11 by connection means such as bonding wires 17. In particular, the interconnects 16 are electrically connected via the bonding wires 17 to, for example, an RF electrode configured to apply a high-speed drive signal to an optical modulator, a DC electrode that applies a DC bias to the optical modulator, an output electrode that outputs a photocurrent from a photodiode, or the like.

In the example of FIG. 2, the photonic IC 105 is mounted on a mount 13 provided at the bottom of the cavity 12. when the photonic IC 105 is fabricated of a semiconductor material, strict temperature control is unnecessary. However, when an electro-optic modulator is integrated in the photonic IC, a temperature control element may be used in place of the mount 13.

The casing 11 is hermetically sealed by the lid 15 to prevent moisture or undesirable substances from entering the cavity 12. With the hermetic sealing, even when an optical element such as a lens is inserted for optical coupling between the optical circuit 106 and an optical fiber, adverse effects on the optical element can be prevented.

The bottom plane of the casing 11 is a heat dissipating plane or a heat sink 14. The heat sink 14 and the mount 13 may be made of the same material having a high thermal conductivity such as AlN or the like. By providing the heat sink 14 on the side opposite to the electrical coupling plane using the solder balls 18, heat generated from the electrical coupling part and the photonic IC 105 can be dissipated to the outside of the casing 11.

In manufacturing the optical component 10, for example, the photonic IC 105 is placed in the cavity 12 of the casing 11, and is connected to the interconnects 16 of the casing 11 by wire bonding. Then the cavity is covered with the lid 15, and the solder balls 18 provided around the lid 15 may be shaped by reflow. Thus the optical component 10 is obtained.

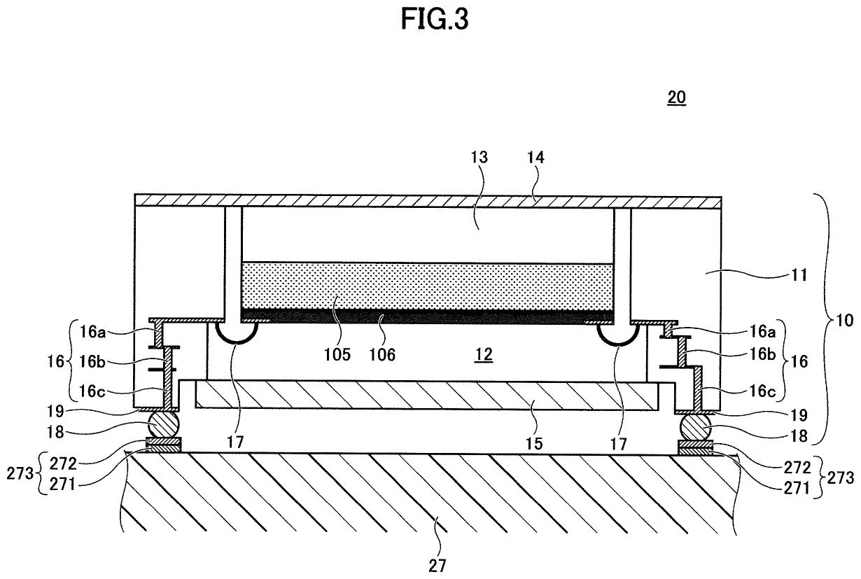

FIG. 3 illustrates an assembled structure 20 with the optical component 10 mounted on the circuit board 27 in a schematic cross-sectional view taken along the line X-X′ line of FIG. 1. The optical component 10 is flip-chip mounted on the circuit board 27. The optical component 10 is positioned in alignment with the circuit board 27 using a flip chip bonder or the like, and the solder ball 18 and the corresponding one of the connection electrodes 273 formed on the circuit board 27 are joined together by reflow.

The connection electrode 273 includes, for example, a first conductive layer 271 provided on the outermost surface of the circuit board 27 and a second conductive layer 272 provided on the first conductive layer 271. The first conductive layer 271 is, for example, a Cu/Au plated layer, and the second conductive layer 272 is a solder layer. The solder layer may be formed of a low-temperature to medium-temperature solder material such as Sn—In—Ag—Bi, Sn—Ag—Bi—Cu, Sn—An—Bi, Sn—Bi, Sn—In, or the like, as well as SnAgCu (SAC).

Because the solder balls 18 of the optical component 10 are provided along the outer periphery of the cavity 12, the connecting area is limited and the strength with respect to stress tends to be insufficient. The bonding strength may be improved by increasing the diameter of the solder balls 18; however, the pitch and the size of the solder balls 18 are determined by the requirement for impedance matching in high-speed data transfer. By sealing the entirety of the optical component 10 with an underfill material, the stress applied to the connected part may be absorbed. However, there may be particular areas where such underfill materials cannot be applied from the viewpoint of eliminating the influence of the dielectric constant in high-speed data transfer.

In the embodiment, the influence of stress due to the difference in thermal expansion coefficient, including a linear expansion coefficient, is reduced by balancing the thermal expansion coefficient (or the linear expansion coefficient) of the entirety of the optical component 10 and that of the circuit board 27. The lid 15 of the optical component 10 is formed of a material with a thermal expansion coefficient greater than that of the circuit board 27 to absorb the difference in the thermal expansion coefficient between the casing 11 and the circuit board 27 at or near the bonding or connecting part. When the linear expansion coefficient of the entirety of the circuit board 27 which includes a resin substrate and metal interconnects formed therein is 14 to 15 ppm/° C., then the linear expansion coefficient of the lid 15 is preferably 17 to 30 ppm/° C. More preferably, the linear expansion coefficient of the entirety of the optical component 10 including the casing 11 and the lid 15 is substantially equal to that of the circuit board 27.

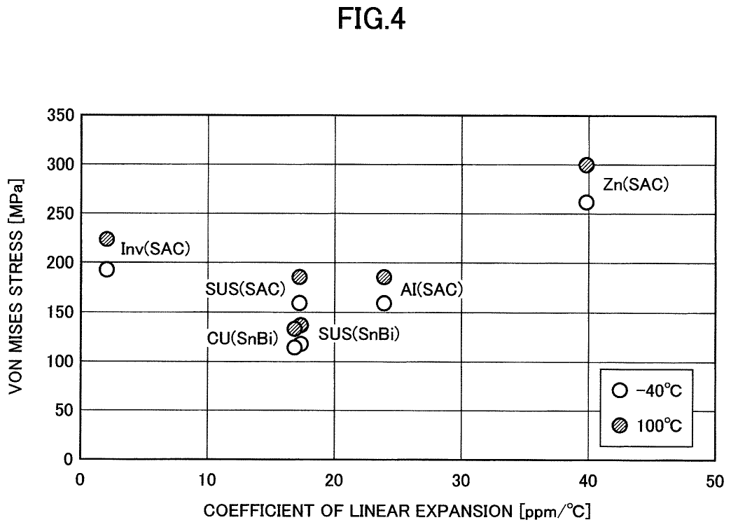

FIG. 4 is a diagram illustrating distribution of stress according to variety of materials for the lid 15. The horizontal axis represents the linear expansion coefficient (ppm/° C.) of the material, and the vertical axis represents Von Mises stress (MPa) applied to the solder ball 18. The material of the solder ball 18 used is denoted in the parentheses after the material name of the lid 15. White circles indicate stress at −40° C., and hatched circles indicate stress at 100° C.

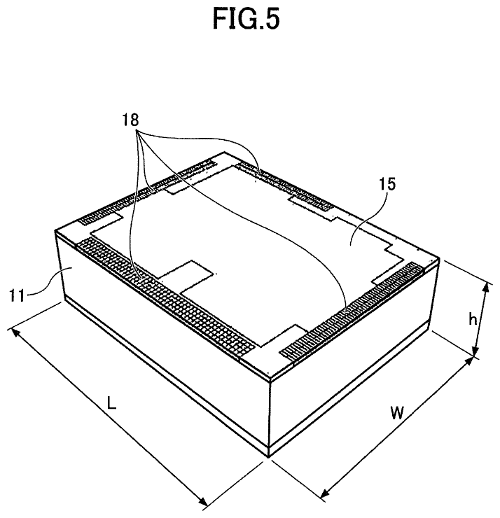

FIG. 5 illustrates a model used for the calculation of FIG. 4. The casing 11 is an alumina case with a bottom size (L×W) of 14 mm×10 mm and a height (h) of 3.5 mm. The total number of solder balls arranged along the outer periphery of the alumina case is 153, each solder ball having a diameter of 200 μm. The material of the lid 15 that covers the solder ball cavity, as well as the material of the solder ball 18 disposed on the outer periphery of the cavity, are varied.

Returning to FIG. 4, it is preferable for the lid 15 to be made of a material having a greater linear expansion coefficient than the circuit board 27. When the linear expansion coefficient of the circuit board, which has metal interconnects formed in a resin substrate, is 13 to 15 ppm/° C., it is desirable for the lid 15 to be made of Cu, Al, Zn, SUS or the like having a greater linear expansion coefficient than the circuit board. The label “Inv” in the figure is a Ni—Fe alloy material. This material has a small coefficient of linear expansion and it cannot sufficiently absorb the difference in stress between the casing 11 and the circuit board 27.

Zinc (Zn) has a large linear expansion coefficient. However, when the lid 15 is made of Zn, the stress applied to the SAC solder balls 18 increases.

Based upon the calculation result of FIG. 4, the stress values are fitted as a function of the linear expansion coefficient. The stress applied to the solder ball 18 is minimized at around 20 ppm/° C., and it is understood that using a material for the lid 15 having a linear expansion coefficient of 18 to 30 ppm/° C. is preferable. In this case, the solder ball material may be a low-temperature solder material such as Sn—Bi or Sn—In, or alternatively, an intermediate temperature solder material such as SAC may be used.

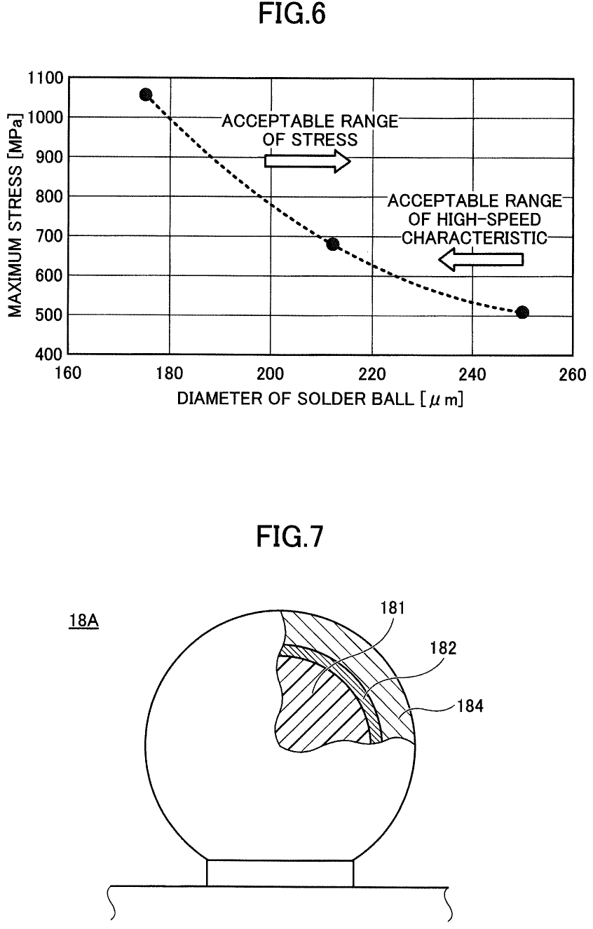

FIG. 6 illustrates the maximum stress applied to the solder ball as a function of the diameter of the solder ball 18. For the solder ball 18, Sn_{95.5}Ag_{3.5}Cu_{0.7} is used.

As the diameter of the solder ball 18 decreases, the stress applied to each solder ball 18 increases. In order for ensuring the connection reliability between the optical component 10 and the circuit board 27, it is desirable for the solder ball 18 to have a diameter of 200 μm or more in the model of FIG. 5. On the other hand, from the viewpoint of maintaining the high-speed transfer characteristics, the diameter of the solder ball 18 is preferably 250 μm or less.

The tendencies of the simulations illustrated in FIG. 4 to FIG. 6 apply not only to solder balls but also to protruding electrodes such as pillar electrodes or column electrodes.

FIG. 7 illustrates another example of the materials for the solder ball 18. In addition to the above-described low to medium temperature solder materials, a Cu core or a heat resistant resin core may be used for the solder balls. In this example, the solder ball 18A is fabricated by plating the resin core 181 with the Ni film 182 and the Su/Ag film 184 in this order.

By using the resin core 181, the stress applied to the solder ball 18A can be reduced. The Cu core also has a stress relaxation effect and is excellent in conductivity. Resin core or Cu core solder balls are easily adjustable in size and melting point by controlling the material and the thickness of the plated layer. In place of the Sn/Ag film 184, a SAC plating film may be used. In this case, resistance to impact shock and temperature cycle performance can be improved.

### Modification 1

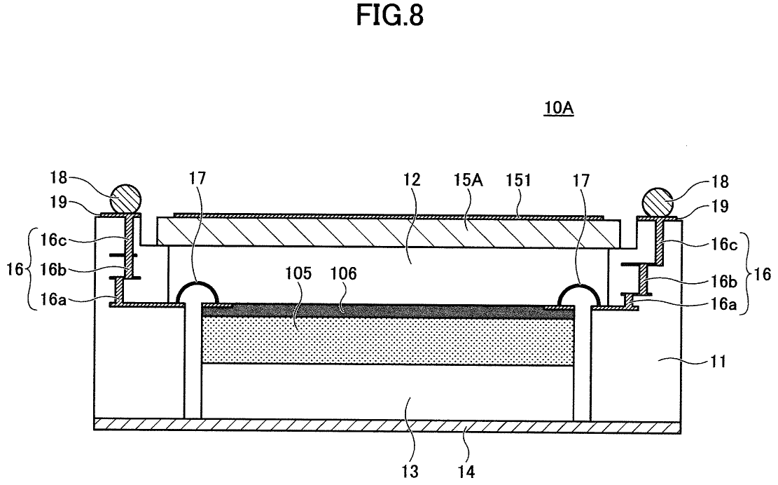

FIG. 8 is a schematic diagram of an optical component 10A, which is a modification of the optical component 10. In the optical component 10A, a surface treatment layer 151 is formed over the outer surface of the lid 15A. The surface treatment layer 151 is, for example, a solderable plated layer (that enables soldering). By providing the surface treatment layer 151 over the top surface of the lid 15A at the opposite side to the back surface thereof facing the cavity 12, the lid 15A can be used as connecting means of the optical component 10A.

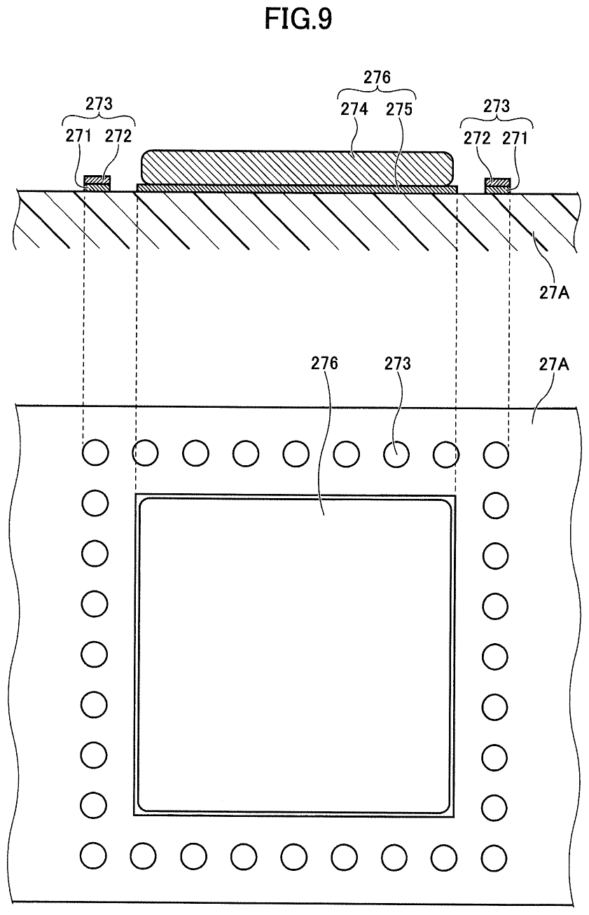

FIG. 9 illustrates a configuration example of a circuit board 27A on which the optical component 10A of FIG. 8 is to be mounted. Connection electrodes 273 are provided on the surface of the circuit board 27A so as to define, for example, a rectangular area, in order for receiving the solder balls 18 of the optical component 10A. The connection electrode 273 may be formed by stacking the first conductive layer 271 and the second conductive layer 272.

An island-like bonding layer 276 is formed inside the array of the connection electrodes 273. The bonding layer 276 may have a stacked structure of a first conductive layer 275 and a second conductive layer 274 provided over the first conductive layer 275. The first conductive layer 275 of the bonding layer 276 may be fabricated in the same process as the first conductive layers 271 of the connection electrodes 273. The bonding layer 276 is thicker than the connection electrode 273. The second conductive layer 274 of the bonding layer 276 may be formed by, for example, applying a solder paste by a printing method, a spray method, or the like. The thickness of the second conductive layer 274 is substantially the same as or in conformity to the height of the solder ball 18 of the optical component 10A.

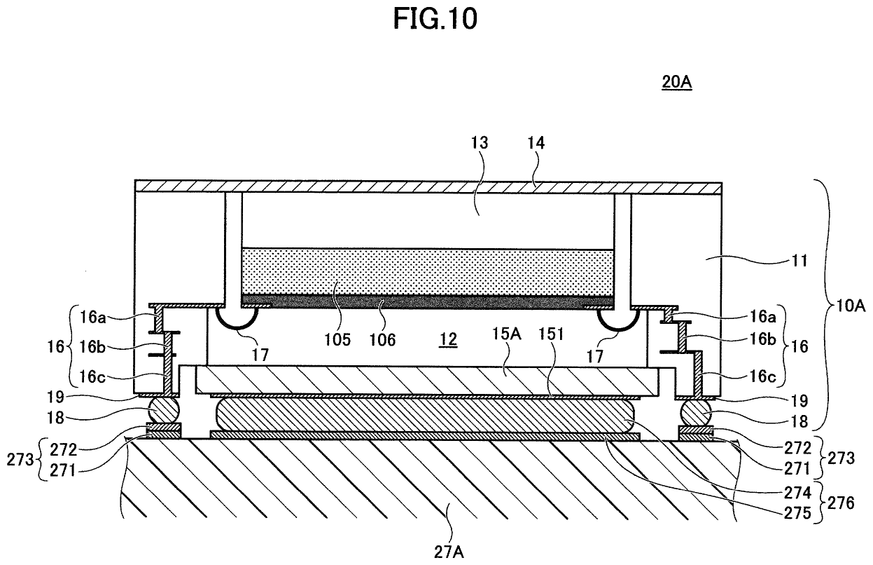

FIG. 10 is a schematic diagram of an assembled structure 20A in which the optical component 10A of FIG. 8 is mounted on the circuit board 27A of FIG. 9. During the reflow process for bonding the solder balls 18 of the optical component 10A onto the connection electrodes 273, the surface treatment layer 151 over the lid 15A of the optical component 10A and the bonding layer 276 of the circuit board 27A also melt and are fixed to each other.

By making use of the lid 15A in bonding the optical component 10A onto the circuit board 27A, the bonding strength between the optical component 10A and the circuit board 27A is enhanced, and the stress concentration on each of the solder balls 18 can be reduced. Consequently, the operational reliabilities of the optical component 10A and the optical module 1 are improved.

### Modification 2

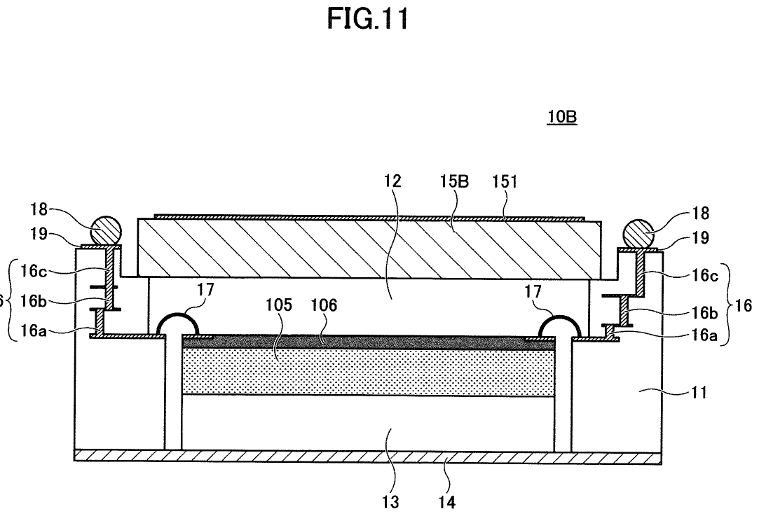

FIG. 11 illustrates an optical component 10B, which is another modification of the optical component 10. The optical component 10B is configured such that the position of the outer surface of the lid 15B and the position of the distal end of the solder ball 18 are aligned in the height direction. In other words, the outer surface of the lid 15B is positioned higher than the upper end face of the casing 11 on which the solder balls 18 are mounted.

A surface treatment layer 151 is formed over the outer surface of the lid 15B. The surface treatment layer 151 is, for example, a solderable plated layer. By providing the surface treatment layer 151 over the top surface of the lid 15B at the opposite side to the back surface thereof facing the cavity 12, the lid 15B can be used as a connecting means of the optical component 10B.

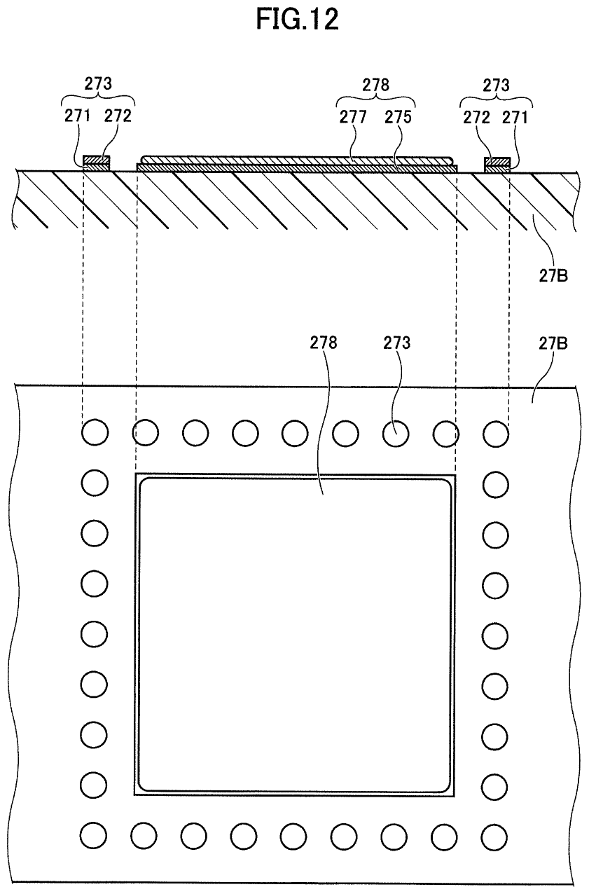

FIG. 12 illustrates a configuration example of a circuit board 27B on which the optical component 10B of FIG. 11 is to be mounted. Connection electrodes 273 are provided on the surface of the circuit board 27B so as to define, for example, a rectangular area, in order for receiving the solder balls 18 of the optical component 10B. The connection electrode 273 may be formed by stacking the first conductive layer 271 and the second conductive layer 272.

A pad-like bonding layer 278 is formed inside the array of the connection electrodes 273. The bonding layer 278 may have a stacked structure of a first conductive layer 275 and a second conductive layer 277 provided over the first conductive layer 275. The first conductive layer 275 of the bonding layer 278 may be fabricated in the same process as the first conductive layers 271 of the connection electrodes 273. The bonding layer 277 of the bonding layer 278 may be fabricated in the same process as the second conductive layer 272 of the connection electrode 273.

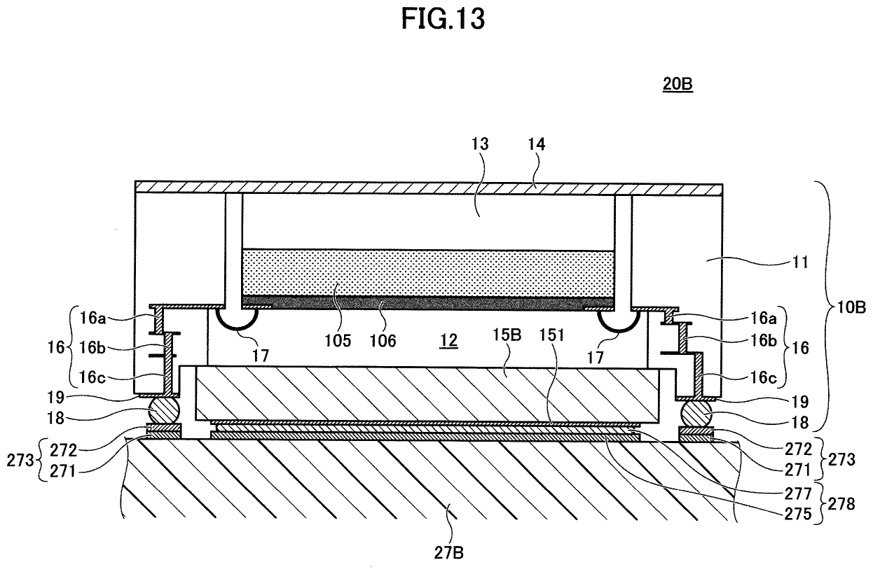

FIG. 13 is a schematic diagram of an assembled structure 20B in which the optical component 10B of FIG. 11 is mounted on the circuit board 27B of FIG. 12. During the reflow process for bonding the solder balls 18 of the optical component 10B onto the connection electrodes 273, the surface treatment layer 151 over the lid 15B of the optical component 10B and the bonding layer 278 of the circuit board 27B also melt and are fixed to each other.

By making use of the lid 15B in bonding the optical component 10B onto the circuit board 27B, the bonding strength between the optical component 10B and the circuit board 27B is enhanced, and the stress concentration on each of the solder balls 18 can be reduced. Consequently, the operational reliabilities of the optical component 10B and the optical module 1 are improved.

### Other Modifications

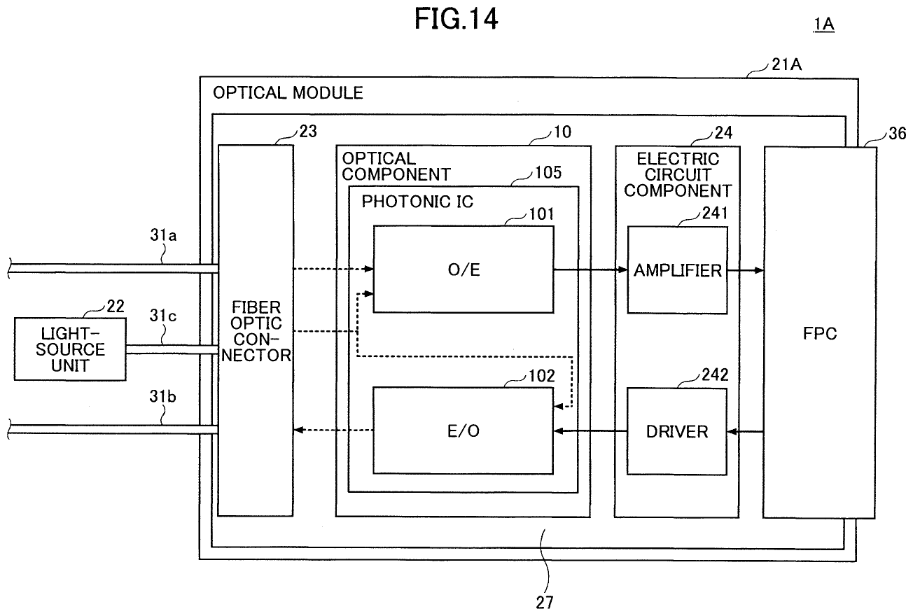

FIG. 14 is a schematic diagram of an optical module 1A on which the optical component 10 is mounted. The optical module 1A serves as an optical frontend module, and it can be used as, for example, a frontend component of a digital coherent transceiver. In place of the optical component 10, either one of the optical components 10A and 10B may be used.

The optical module 1A has a circuit board 27 in a package 21A. On the circuit board 27 are mounted an optical component 10 and an electric circuit component 24. An optical fiber 31a for inputting a received signal light, an optical fiber 31b for outputting a signal light to be transmitted, and an optical fiber 31c for inputting light from the light source unit 22 are connected to the optical module 1A by an optical connector 23, to input and output light beams to and from the optical component 10.

The optical component 10 is flip-chip mounted on the circuit board 27, and electrically connected to the electric circuit component 24. The electric circuit component 24 is connected to an external signal processing circuit (such as a DSP) via, for example, a flexible print circuit (FPC) board 36 for high-speed input and output of electric signals. The optical module 1A may be further provided with input/output terminals for the purpose of control operations, other than the FPC board 36.

Operations of the photonic IC 105 of the optical component 10 and operations of the electric circuit component 24 are the same as those described in connection with FIG. 1, and therefore, redundant explanation is omitted.

The photonic IC 105 is provided in the cavity 12 of the optical component 10 and is hermetically sealed by the lid 15. Because the optical component 10 is designed such that the overall thermal expansion coefficient of the combination of the lid 15 and the casing 11 is balanced with the thermal expansion coefficient of the circuit board 27, the stress applied to the solder balls 18 in the connecting part is reduced. When a surface treatment layer 151 formed of a solderable plating material is provided over the outer surface of the lid 15, as in the lid 15A and 15B of the modifications, the connecting area size between the optical component 10 and the circuit board 27 is increased, and bonding reliability is improved.

The optical component and the optical module to which the optical component is applied are not limited to the above-described configuration examples. For example, the optical module may be configured as an optical transmitter module or an optical receiver module. When the optical component 10 is applied to an optical transmitter module, a lithium niobate (LiNbO₃) electro optic modulator may be accommodated in the cavity 12 of the ceramic electrical insulating casing 11. With this configuration, a hermetically sealed package can be assembled with the ceramic insulator and the lid 15, thereby preventing moisture from entering the package. A temperature control element may be provided in place of the mount 13.

When the optical component 10 is applied to an optical receiver module, the photonic IC 105 may be formed of a compound semiconductor such as indium phosphide (InP), and photodiodes (PD) and a 90-degree hybrid optical mixer may be fabricated in the integrated circuit.

In any modifications or alterations, the casing 11 for accommodating the photonic IC 105 and the lid 15 are designed such that the thermal expansion coefficient of the optical component 10 balances with the thermal expansion coefficient of the circuit board 27. Accordingly, the stress applied to the connecting part of the optical component 10 can be reduced, and connection reliability can be improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of superiority or inferiority of the invention. Although the embodiments of the present inventions have been described in detail, it should be understood that the various changes, substitutions, and alterations could be made hereto without departing from the spirit and scope of the invention.

What is claimed is:

1. An optical component configured to be mounted on a circuit board, comprising:
a casing made of a ceramic electrical insulator and having a cavity;
a photonic circuit device provided in the cavity;
a lid configured to cover the cavity; and
protruding electrodes provided along an outer periphery of the cavity of the casing,
wherein a first linear expansion coefficient of the casing is smaller than a second linear expansion coefficient of the circuit board, and a third linear expansion coefficient of the lid is greater than the second linear expansion coefficient of the circuit board.

2. The optical component as claimed in claim 1, wherein an overall linear expansion coefficient of a combination of the casing and the lid is balanced with the second linear expansion coefficient of the circuit board.

3. The optical component as claimed in claim 1, wherein a position of an outer surface of the lid opposite to the cavity is aligned with a distal end of the protruding electrodes in a height direction.

4. The optical component as claimed in claim 1, wherein a position of an outer surface of the lid opposite to the cavity is lower than a distal end of the protruding electrode in a height direction.

5. The optical component as claimed in claim 1, wherein an outer surface of the lid opposite to the cavity is provided with surface treatment that enables soldering.

6. The optical component as claimed in claim 1, wherein a bottom surface of the casing opposite to the lid is a heat dissipating surface.

7. The optical component as claimed in claim 1, wherein the protruding electrodes are solder balls with a resin core or a copper core.

8. The optical component as claimed in claim 1, wherein a diameter of the protruding electrodes is 200 μm to 250 μm.

9. The optical component as claimed in claim 1,
wherein the casing has an electric interconnect formed in the casing, and
wherein at least a part of the protruding electrodes is connected to the photonic circuit device through the electric interconnect.

10. The optical component as claimed in claim 1,
wherein the casing has an electric interconnect formed in the casing, and
wherein the photonic circuit device is connected to the electric interconnect by wire bonding.

11. An optical module comprising:
a circuit board; and
an optical component flip-chip mounted on the circuit board,
wherein the optical component has
a casing made of a ceramic electrical insulator and having a cavity,
a photonic circuit device provided in the cavity,
a lid configured to cover the cavity, and
protruding electrodes provided along an outer periphery of the cavity of the casing,
wherein a first linear expansion coefficient of the casing is smaller than a second linear expansion coefficient of the circuit board, and a third linear expansion coefficient of the lid is greater than the second linear expansion coefficient of the circuit board.

12. The optical module as claimed in claim 11,
wherein the circuit board has an array of connection electrodes connected to the protruding electrodes of the optical component, and a bonding layer provided inside the array of the connection electrodes, and
wherein the lid is fixed to the bonding layer.

13. The optical module as claimed in claim 12, wherein the bonding layer is thicker than the connection electrode, and a thickness of the bonding layer conforms to a height of the protruding electrodes.

14. The optical module as claimed in claim 12,
wherein the bonding layer has a same thickness as the connection electrode, and
wherein a position of an outer surface of the lid of the optical component is aligned with a distal end of the protruding electrodes in a height direction.

15. The optical module as claimed in claim 11,
wherein the photonic circuit device has at least one of an optical to electric converter circuit and an electric to optical converter circuit, and
wherein the optical component is mounted together with an electric circuit component on the circuit board.

16. The optical module as claimed in claim 15, further comprising:
an optical connector configured to connect the optical component to an external fiber optic cable; and
an electrical connector configured to connect the electric circuit component to an external apparatus.
